(19) United States
(12) Patent Application Publication
(10) Pub. No.: US 2025/0267949 A1
(43) Pub. Date: Aug. 21, 2025

(54) MATCHING LAYOUT CIRCUIT AND MANUFACTURING METHOD THEREOF

(71) Applicant: REALTEK SEMICONDUCTOR CORPORATION, Hsinchu (TW)

(72) Inventor: JHIH-LONG PENG, Hsinchu (TW)

(21) Appl. No.: 18/916,146

(22) Filed: Oct. 15, 2024

(30) Foreign Application Priority Data
Feb. 16, 2024 (TW) 113105579

(51) Int. Cl. H01L 27/02; H01L 23/544; H01L 25/11

(52) U.S. Cl. CPC H10D 89/10; H01L 23/544; H01L 25/115

(57) ABSTRACT

A matching layout circuit includes a medium mismatch mark, a basic mismatch mark, and a dummy mark. The medium mismatch mark is disposed in a center of the matching layout circuit, and includes a plurality of first transistors. The first transistors are disposed in the medium mismatch mark, and configured to receive a first current. The basic mismatch mark is disposed outside the medium mismatch mark, and includes a plurality of second transistors. The second transistors are disposed in the basic mismatch mark, and configured to receive a second current. A first accuracy of the first current is higher than a second accuracy of the second current. The dummy mark is disposed outside the basic mismatch mark, and includes a plurality of third transistors. The third transistors are disposed in the dummy mark. The sizes of the first transistors, the second transistors, and the third transistors are the same.

### BACKGROUND OF THE INVENTION

### 1. Field of the Invention

The present disclosure relates to a matching layout circuit and a manufacturing method thereof, especially to a matching layout circuit and a manufacturing method thereof that integrate a medium mismatch mark and a basic mismatch mark.

### 2. Description of Related Art

In analog circuits, transistors needing high current accuracy are required to be disposed away from the outermost transistors to ensure that the current inaccuracy is small during fabrication. To achieve the goal, conventional analog circuits place a dummy mark surrounding the transistors needing high current accuracy, and place transistors in the dummy mark for a protective purpose. However, the dummy mark will consume a significant amount of area, which is highly disadvantageous for circuit design and layout.

### SUMMARY OF THE INVENTION

In some aspects, an object of the present disclosure is to, but not limited to, provide a matching layout circuit and a manufacturing method thereof that makes an improvement to the prior art.

An embodiment of the matching layout circuit of the present disclosure includes a medium mismatch mark, a basic mismatch mark, and a dummy mark. The medium mismatch mark is disposed in a center of the matching layout circuit, and includes a plurality of first transistors. The first transistors are disposed in the medium mismatch mark, and configured to receive a first current. The basic mismatch mark is disposed outside the medium mismatch mark, and includes a plurality of second transistors. The second transistors are disposed in the basic mismatch mark, and configured to receive a second current. A first accuracy of the first current is higher than a second accuracy of the second current. The dummy mark is disposed outside the basic mismatch mark, and includes a plurality of third transistors. The third transistors are disposed in the dummy mark. The sizes of the first transistors, the second transistors, and the third transistors are the same.

An embodiment of the manufacturing method of the matching layout circuit of the present disclosure includes following steps: disposing a medium mismatch mark in a center of the matching layout circuit; disposing a plurality of first transistors in the medium mismatch mark, wherein the first transistors are configured to receive a first current; disposing a basic mismatch mark outside the medium mismatch mark; disposing a plurality of second transistors in the basic mismatch mark, wherein the second transistors are configured to receive a second current, wherein a first accuracy of the first current is higher than a second accuracy of the second current; disposing a dummy mark outside the basic mismatch mark; and disposing a plurality of third transistors in the dummy mark, wherein sizes of the first transistors, the second transistors and the third transistors are the same.

Technical features of some embodiments of the present disclosure make an improvement to the prior art. The matching layout circuit and the manufacturing method thereof of the present disclosure integrate the medium mismatch mark and the basic mismatch mark. Specifically, the present disclosure will make good use of the dummy mark outside the medium mismatch mark by changing the dummy mark designated only for protection into the basic mismatch mark to effectively save areas without affecting the characteristics of the circuit for facilitating circuit design and layout.

These and other objectives of the present invention will no doubt become obvious to those of ordinary skill in the art after reading the following detailed description of the preferred embodiments that are illustrated in the various figures and drawings.

### BRIEF DESCRIPTION OF THE DRAWINGS

FIG. 1 shows an embodiment of a matching layout circuit of the present disclosure.

FIG. 2 shows an embodiment of a matching layout circuit of the present disclosure.

FIG. 3 shows an embodiment of a portion circuit of a matching layout circuit of the present disclosure.

FIG. 4 shows an embodiment a flowchart of a manufacturing method of a matching layout circuit of the present disclosure.

### DETAILED DESCRIPTION OF THE PREFERRED EMBODIMENTS

To improve the issue of significant area consumption caused by dummy marks in analog circuits in prior art, which is highly disadvantageous for circuit design and layout, the present disclosure provides a matching layout circuit and a manufacturing method thereof, which will be explained in detail as shown below.

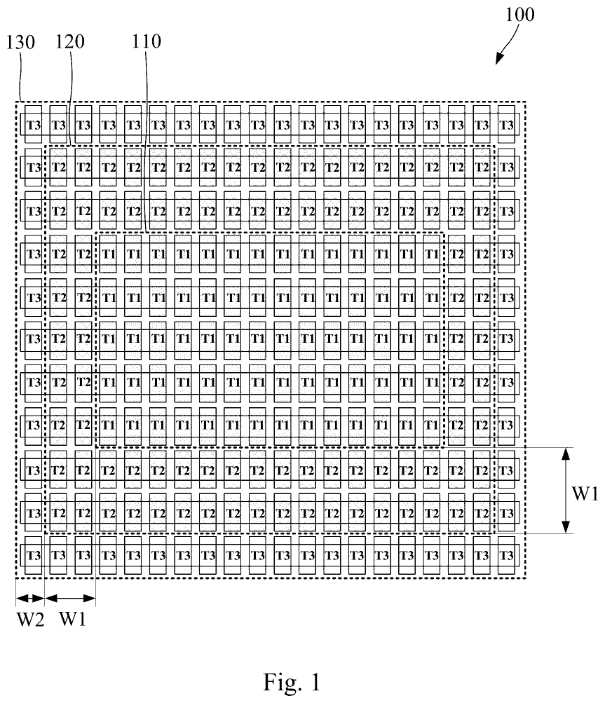

FIG. 1 shows an embodiment of a matching layout circuit 100 of the present disclosure. As shown in the figure, the matching layout circuit 100 includes a medium mismatch mark 110, a basic mismatch mark 120, and a dummy mark 130. The medium mismatch mark 110 is disposed in a center of the matching layout circuit 100, and includes a plurality of first transistors T1. The plurality of first transistors T1 are disposed in the medium mismatch mark 110, and configured to receive a first current.

Besides, the basic mismatch mark 120 is disposed outside the medium mismatch mark 110, and includes a plurality of second transistors T2. The plurality of second transistors T2 are disposed in the basic mismatch mark 120, and configured to receive a second current. Since the basic mismatch mark 120 is disposed outside the medium mismatch mark 110, the first transistors T1 of the medium mismatch mark 110 are disposed away from the outermost transistors. Therefore, the accuracies of the first currents of the first transistors T1 of the medium mismatch mark 110 are high, and the first transistors T1 are suitable for use in circuits such as Bandgap circuits, operational amplifiers (OPAMPs), and current mirrors, which require high current accuracy. The accuracies of the second currents of the second transistors T2 of the basic mismatch mark 120 are lower than the accuracies of the first currents, and the second transistors T2 are suitable for use in circuits like current mirrors and analog differential pairs.

In addition, the dummy mark 130 is disposed outside the basic mismatch mark 120, and includes a plurality of third transistors T3. The plurality of third transistors T3 are disposed in the dummy mark 130. The sizes of the plurality of first transistors T1, the plurality of second transistors T2, and the plurality of third transistors T3 are the same. Since the dummy mark 130 is disposed outside the basic mismatch mark 120, and the sizes of the first transistors T1, the second transistors T2, and the third transistors T3 are the same, the requirement for disposing transistors with the same size outside the basic mismatch mark 120 can be met.

As shown in FIG. 1, the matching layout circuit 100 of the present disclosure integrates the medium mismatch mark 110 and the basic mismatch mark 120. Specifically, the present disclosure will make good use of the dummy mark outside the medium mismatch mark 110 by changing the dummy mark designated only for protection into the basic mismatch mark 120 to effectively save areas without affecting the characteristics of the circuit for facilitating circuit design and layout.

In some embodiments, the matching layout circuit 100 which integrates (e.g., combines) the medium mismatch mark (MMM) 110 and the basic mismatch mark (BMM) 120 can save areas effectively, which can be seen in the following table 1:

TABLE 1
the comparison table of the matching layout circuit

| | BMM | MMM | Combination | Reduction rate |
|---|---|---|---|---|
| PMOS Area(μm²) | 840.06 | 1149.77 | 1149.77 | 42.22% |
| NMOS Area(μm²) | 811.14 | 1857.84 | 1857.84 | 30.39% |
| Area(μm²) | 1651.20 | 3007.61 | 3007.61 | 35.44% |

As can be seen in table 1, assuming the area of the basic mismatch mark (BMM) is 1651.20 μm², the area of the medium mismatch mark (MMM) is 3007.61 μm², and the total area when the two mismatch marks are separately used in the circuit is 4658.81 μm². However, if the combination manner of the present disclosure is utilized to integrate the two mismatch marks, the combination area is 3007.61 μm². In view of the above, the area of the matching layout circuit of the present disclosure can effectively reduce by 35.44%. Similarly, taking P-type Metal Oxide Semiconductor Field Effect Transistors (PMOS) as example, the area of the matching layout circuit of the present disclosure can effectively reduce by 42.22%. Besides, taking N-type Metal Oxide Semiconductor Field Effect Transistors (NMOS) as example, the area of the matching layout circuit of the present disclosure can effectively reduce by 30.39%.

In some embodiments, the basic mismatch mark 120 surrounds the medium mismatch mark 110. In some embodiments, the width W1 of the basic mismatch mark 120 is larger than or equal to 5 micrometers (μm).

In some embodiments, the dummy mark 130 surrounds the basic mismatch mark 120. It is noted that the width W2 of the dummy mark 130 is unrestricted, and the dummy mark 130 outside the basic mismatch mark 120 merely needs disposing transistors with the same size. In some embodiments, the width W2 of the dummy mark 130 is required to be only the width of a single transistor. In some embodiments, the width W2 of the dummy mark 130 can range from 1 micrometer (μm) to 4 micrometers (μm). In some embodiments, the width W2 of the dummy mark 130 can be 2 micrometers (μm) or 3 micrometers (μm) depending on actual requirements. In some embodiments, the base (e.g., bulk) of each of the third transistors T3 of the dummy mark 130 is coupled to the gate, the source, and the drain. For example, the gate, the source, the drain, and the base of the third transistor T3 of the dummy mark 130 are coupled together. In another embodiment, the gate, the source, the drain, and the base of the third transistor T3 within the dummy mark 130 can utilize other coupling manners to achieve area savings.

In some embodiments, the medium mismatch mark 110, the basic mismatch mark 120, and the dummy mark 130 are arranged in sequence from an inner side of the matching layout circuit 100 to an outer side of the matching layout circuit 100. In some embodiments, the medium mismatch mark 110 is located at the innermost side (e.g., the center) of the matching layout circuit 100, the basic mismatch mark 120 is located between the medium mismatch mark 110 and the dummy mark 130, and the dummy mark 130 is located at the outermost side of the matching layout circuit 100.

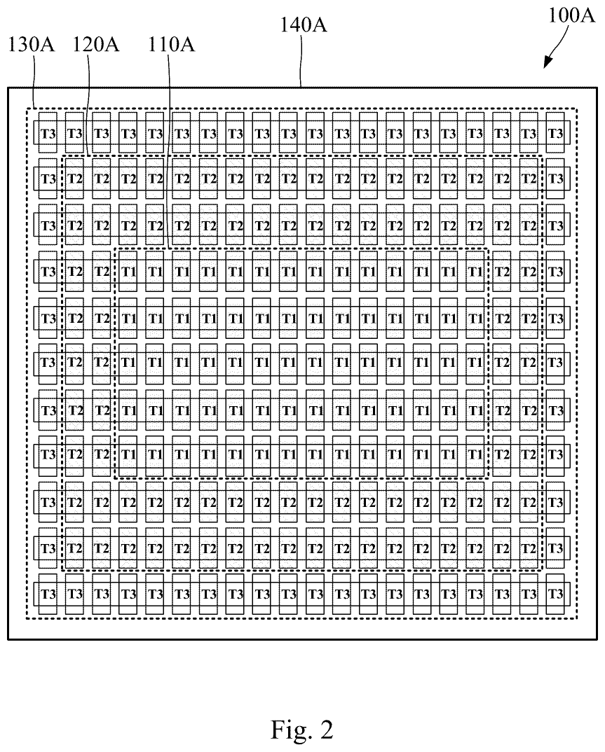

FIG. 2 shows an embodiment of a matching layout circuit 100A of the present disclosure. Compared with the matching layout circuit 100 in FIG. 1, the matching layout circuit 100A in FIG. 2 further includes a guard ring 140A. The guard ring 140A is disposed outside the matching layout circuit 100A. Each of the second transistors T2 inside the guard ring 140A includes a plurality of terminals (e.g., the gate, the source, the drain, and the base), and the voltages of the terminals are different. It is noted that the components in the embodiment of FIG. 2 labeled similarly to those of FIG. 1 have similar structures and electrical characteristics, and detailed descriptions related to the above-mentioned components in FIG. 2 will be omitted herein for brevity.

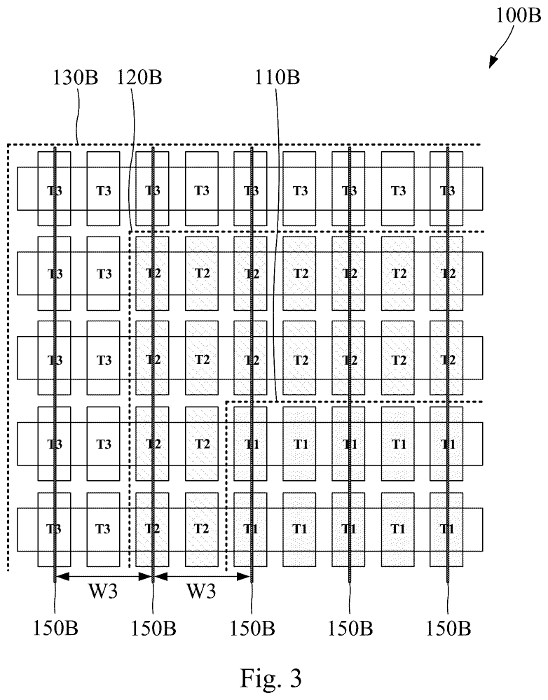

FIG. 3 shows an embodiment of a portion circuit of a matching layout circuit 100B of the present disclosure. Compared with the matching layout circuit 100 in FIG. 1, the matching layout circuit 100B in FIG. 3 further includes a plurality of metal structures (e.g., ultra thick metal, UTM) 150B. The plurality of metal structures 150B uniformly cover the medium mismatch mark 110B, the basic mismatch mark 120B, and the dummy mark 130B. In some embodiments, the plurality of metal structures 150B cover the medium mismatch mark 110B, the basic mismatch mark 120B, and the dummy mark 130B, and the metal structure 150B are evenly spaced from each other. For example, the metal structures 150B are evenly spaced from each other by a distance of width W3. It is noted that the components in the embodiment of FIG. 3 labeled similarly to those of FIG. 1 have similar structures and electrical characteristics, and detailed descriptions related to the above-mentioned components in FIG. 3 will be omitted herein for brevity.

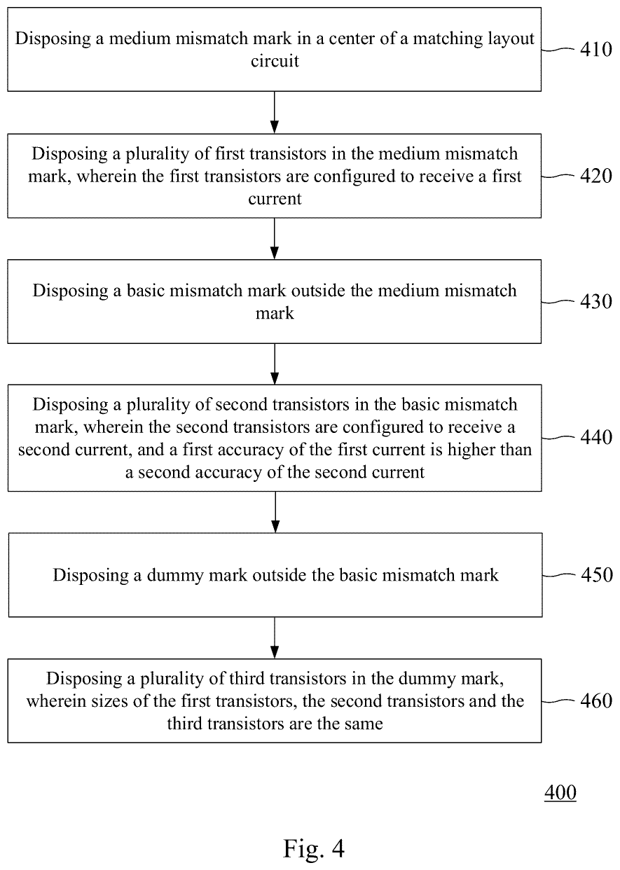

FIG. 4 shows an embodiment a flowchart of a manufacturing method 400 of a matching layout circuit of the present disclosure. Reference is now made to FIG. 1 and FIG. 4. In step 410, disposing a medium mismatch mark 110 in a center of a matching layout circuit 100. In step 420, disposing a plurality of first transistors T1 in the medium mismatch mark 110. The first transistors T1 are configured to receive a first current.

In step 430, disposing a basic mismatch mark 120 outside the medium mismatch mark 110. In step 440, disposing a plurality of second transistors T2 in the basic mismatch mark 120. The second transistors T2 are configured to receive a second current, and a first accuracy of the first current is higher than a second accuracy of the second current. Since the basic mismatch mark 120 is disposed outside the medium mismatch mark 110, the first transistors T1 of the medium mismatch mark 110 are disposed away from the outermost transistors. Therefore, the accuracies of the first currents of the first transistors T1 of the medium mismatch mark 110 are high, and the first transistors T1 are suitable for use in circuits such as Bandgap circuits, operational amplifiers (OPAMPs), and current mirrors, which require high current accuracy. The accuracies of the second currents of the second transistors T2 of the basic mismatch mark 120 are lower than the accuracies of the first currents, and the second transistors T2 are suitable for use in circuits like current mirrors and analog differential pairs.

In step 450, disposing a dummy mark 130 outside the basic mismatch mark 120. In step 460, disposing a plurality of third transistors T3 in the dummy mark 130. Sizes of the first transistors T1, the second transistors T2, and the third transistors T3 are the same. Since the dummy mark 130 is disposed outside the basic mismatch mark 120, and the sizes of the first transistors T1, the second transistors T2, and the third transistors T3 are the same, the requirement for disposing transistors with the same size outside the basic mismatch mark 120 can be met. It is noted that structures and electrical characteristics of the matching layout circuit 100 manufactured by the manufacturing method 400 are described in detail in the embodiments of FIG. 1 to FIG. 3, and detailed descriptions related to the above-mentioned structures and electrical characteristics will be omitted herein for brevity.

It is noted that the present disclosure is not limited to the embodiments as shown in FIG. 1 to FIG. 4, it is merely an example for illustrating one of the implements of the present disclosure, and the scope of the present disclosure shall be defined on the bases of the claims as shown below. In view of the foregoing, it is intended that the present disclosure covers modifications and variations to the embodiments of the present disclosure, and modifications and variations to the embodiments of the present disclosure also fall within the scope of the following claims and their equivalents.

As described above, technical features of some embodiments of the present disclosure make an improvement to the prior art. The matching layout circuit and the manufacturing method thereof of the present disclosure integrate the medium mismatch mark and the basic mismatch mark. Specifically, the present disclosure will make good use of the dummy mark outside the medium mismatch mark by changing the dummy mark designated only for protection into the basic mismatch mark to effectively save areas without affecting the characteristics of the circuit for facilitating circuit design and layout.

It is noted that people having ordinary skill in the art can selectively use some or all of the features of any embodiment in this specification or selectively use some or all of the features of multiple embodiments in this specification to implement the present invention as long as such implementation is practicable; in other words, the way to implement the present invention can be flexible based on the present disclosure.

The aforementioned descriptions represent merely the preferred embodiments of the present invention, without any intention to limit the scope of the present invention thereto. Various equivalent changes, alterations, or modifications based on the claims of the present invention are all consequently viewed as being embraced by the scope of the present invention.

What is claimed is:

1. A matching layout circuit, comprising:
a medium mismatch mark, disposed in a center of the matching layout circuit, comprising:
a plurality of first transistors, disposed in the medium mismatch mark, and configured to receive a first current;
a basic mismatch mark, disposed outside the medium mismatch mark, comprising:
a plurality of second transistors, disposed in the basic mismatch mark, and configured to receive a second current, wherein a first accuracy of the first current is higher than a second accuracy of the second current; and
a dummy mark, disposed outside the basic mismatch mark, comprising:
a plurality of third transistors, disposed in the dummy mark, wherein sizes of the first transistors, the second transistors and the third transistors are a same.

2. The matching layout circuit of claim 1, wherein the basic mismatch mark surrounds the medium mismatch mark.

3. The matching layout circuit of claim 1, wherein the dummy mark surrounds the basic mismatch mark.

4. The matching layout circuit of claim 1, wherein the medium mismatch mark, the basic mismatch mark, and the dummy mark are arranged in sequence from an inner side of the matching layout circuit to an outer side of the matching layout circuit.

5. The matching layout circuit of claim 1, wherein the basic mismatch mark is disposed between the medium mismatch mark and the dummy mark.

6. The matching layout circuit of claim 1, wherein a width of the basic mismatch mark is larger than or equal to 5 micrometers (μm).

7. The matching layout circuit of claim 1, further comprising:
a guard ring, disposed outside the matching layout circuit, wherein each of the second transistors inside the guard ring comprises a plurality of terminals, and voltages of the terminals are different.

8. The matching layout circuit of claim 1, wherein a base of each of the third transistors is coupled to a gate, a source, and a drain.

9. The matching layout circuit of claim 1, further comprising:
a plurality of metal structures, uniformly covering the medium mismatch mark, the basic mismatch mark, and the dummy mark.

10. The matching layout circuit of claim 1, further comprising:
a plurality of metal structures, covering the medium mismatch mark, the basic mismatch mark, and the dummy mark, wherein the metal structures are evenly spaced from each other.

11. A manufacturing method of a matching layout circuit, comprising:
disposing a medium mismatch mark in a center of the matching layout circuit;
disposing a plurality of first transistors in the medium mismatch mark, wherein the first transistors are configured to receive a first current;
disposing a basic mismatch mark outside the medium mismatch mark;
disposing a plurality of second transistors in the basic mismatch mark, wherein the second transistors are configured to receive a second current, and a first accuracy of the first current is higher than a second accuracy of the second current;
disposing a dummy mark outside the basic mismatch mark; and
disposing a plurality of third transistors in the dummy mark, wherein sizes of the first transistors, the second transistors, and the third transistors are a same.

12. The manufacturing method of claim 11, wherein disposing the basic mismatch mark outside the medium mismatch mark comprises:
disposing the basic mismatch mark surrounding the medium mismatch mark.

13. The manufacturing method of claim 11, wherein disposing the dummy mark outside the basic mismatch mark comprises:
disposing the dummy mark surrounding the basic mismatch mark.

14. The manufacturing method of claim 11, wherein the medium mismatch mark, the basic mismatch mark, and the dummy mark are arranged in sequence from an inner side of the matching layout circuit to an outer side of the matching layout circuit.

15. The manufacturing method of claim 11, wherein the basic mismatch mark is disposed between the medium mismatch mark and the dummy mark.

16. The manufacturing method of claim 11, wherein a width of the basic mismatch mark is larger than or equal to 5 micrometers (μm).

17. The manufacturing method of claim 11, further comprising:
disposing a guard ring outside the matching layout circuit, wherein each of the second transistors inside the guard ring comprises a plurality of terminals, and voltages of the terminals are different.

18. The manufacturing method of claim 11, wherein a base of each of the third transistors is coupled to a gate, a source, and a drain.

19. The manufacturing method of claim 11, further comprising:
uniformly covering a plurality of metal structures above the medium mismatch mark, the basic mismatch mark, and the dummy mark.

20. The manufacturing method of claim 11, further comprising:
covering a plurality of metal structures above the medium mismatch mark, the basic mismatch mark, and the dummy mark, wherein the metal structures are evenly spaced from each other.
